(19) United States
(12) Patent Application Publication
(10) Pub. No.: US 2008/0211063 A1
(43) Pub. Date: Sep. 4, 2008

(54) Semiconductor wafer and manufacturing method of semiconductor device

(75) Inventors: Shinichi Adachi, Obu-city (JP); Nobuhiro Tsuji, Okazaki-city (JP); Shoichi Yamauchi, Obu-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/071,927

(22) Filed: Feb. 28, 2008

(30) Foreign Application Priority Data
Mar. 2, 2007 (JP) 2007-53149

(51) Int. Cl. H01L 23/544; H01L 21/20

(52) U.S. Cl. 257/620; 438/401; 257/E23.179; 257/E21.09

(57) ABSTRACT

A semiconductor wafer includes a semiconductor substrate, a semiconductor layer, and an oxide layer. The semiconductor layer is disposed on a surface of the semiconductor substrate and has a crystal structure similar to a crystal structure of the semiconductor substrate. The semiconductor layer includes an element section and a scribe section. The scribe section is disposed to divide the element section into a plurality of portions and is configurated to be used as a cutting allowance for dicing. Each of the portions includes a column structure in which columns having different conductivity types are arranged alternately. The oxide layer is disposed on a surface of the scribe section to be exposed to an outside of the semiconductor device.

### CROSS REFERENCE TO RELATED APPLICATION

This application is based on Japanese Patent Application No. 2007-53149 filed on Mar. 2, 2007, the content of which is incorporated herein by reference in its entirety.

### BACKGROUND OF THE INVENTION

1. Field of the Invention

The present invention relates to a semiconductor wafer and a manufacturing method of a semiconductor device including the semiconductor wafer.

2. Description of the Related Art

A semiconductor wafer and a manufacturing method of a semiconductor device according to a related art including JP-2005-286090A will be described with reference to FIGS. 8A-8C.

At first, as shown in FIG. 8A, a high concentration N-type semiconductor substrate 100, e.g., made of single crystal silicon, is prepared. Then, a low concentration N-type semiconductor layer 200 having a crystal structure similar to that of the semiconductor substrate 100 is formed on an upper surface of the semiconductor substrate 100 by an epitaxy method. Next, as shown in FIG. 8B, a plurality of trenches 230 and the a plurality of trenches 240 are formed at an element section 210 and a scribe section of the semiconductor layer 200, respectively, by etching. The trenches 230 and 240 extend from an upper surface of the semiconductor layer 200 to the upper surface of the semiconductor substrate 100. The element section 210 is a portion in which a semiconductor element will be formed at a later process, and the scribe section 220 will be used as a cutting allowance for dicing. An interval between the trenches 240 formed at the scribe section 220 is smaller than the interval between the trenches 230 formed at the element section 210.

Next, as shown in FIG. 8C, a low concentration P-type epitaxial layer 300 having a crystal structure similar to that of the semiconductor substrate 100 is deposited on an upper surface of the semiconductor layer 200 while being filled into the trenches 230 and 240. Thereby, columns having different conductivity types are arranged alternately at the element section 210 and the scribe section 220. A column structure configurated at the scribe section 220 has a different purpose from a column structure configurated at the element section 210. A portion of the epitaxial layer 300 formed on the trenches 230 and 240 has a thickness different from that of another portion of the epitaxial layer 300 formed on the semiconductor layer 200. Thus, a step D is provided as shown in FIG. 8C. Because the interval between the trenches 230 is different from the interval between the trenches 240, an interval between stepped portions at the element section 210 is different from that in the scribe section 220. Thus, the element section 210 and the scribe section 220 can be discriminated based on the interval of the stepped portions. As a result, the column structure configurated at the scribe section 220 functions as a reference position (i.e., an alignment mark) of a mask for forming the semiconductor element at the element section 210 at the later process. In this way, a semiconductor wafer 400 having the stepped portions on an upper surface thereof is formed.

When the semiconductor wafer 400 is used without a processing, the element section 210 and the scribe section 220 can be discriminated based on the interval between the stepped portions provided on the upper surface of the semiconductor wafer 400 (i.e., the alignment mark). However, as shown in FIG. 8D, the upper surface of the semiconductor wafer 400 is generally planarized by polishing before forming the semiconductor element at the element section 210. Because the alignment mark cannot be distinguished after the upper surface of the semiconductor wafer 400 is planarized, it is difficult to discriminate between the element section 210 and the scribe section 220.

Specifically, as shown in FIG. 8C, the P-type epitaxial layer 300 is formed in the trenches 230 by the epitaxy method. Because the semiconductor substrate 100 is made of single crystal silicon, the epitaxial layer 300, which is formed on the semiconductor substrate 100, is also made of single crystal silicon by inheriting the crystal structure of the semiconductor substrate 100. Additionally, the semiconductor layer 200 is also made of single crystal silicon. Thus, the epitaxial layer 300 and the semiconductor layer 200 have optical properties similar to each other, and thereby it is difficult to discriminate between the epitaxial layer 300 and the semiconductor layer 220 after the upper surface of the semiconductor wafer 400 is planarized.

Furthermore, the planarization of the upper surface of the semiconductor wafer 400 is performed based on time. For example, the upper surface of the semiconductor wafer 400 is polished by using a polishing cloth for a predetermined time. When the planarization is performed based only on time, a thickness of a center portion of the semiconductor wafer 400 may be larger or smaller than an outer peripheral portion of the semiconductor wafer 400 as shown in FIGS. 9A and 9B. Thus, the planarization may not be performed with a sufficient accuracy.

### SUMMARY OF THE INVENTION

It is therefore an object of the present invention to provide a semiconductor wafer and a manufacturing method of a semiconductor device in which an element section and a scribe section can be discriminated even after a planarization process.

According to a first aspect of the invention, a method of manufacturing a semiconductor device, includes: preparing a semiconductor wafer that includes a semiconductor substrate and a semiconductor layer, in which the semiconductor layer is stacked on an upper surface of the semiconductor substrate and has a crystal structure similar to a crystal structure of the semiconductor substrate, and the semiconductor wafer includes an element section configured to have a semiconductor element and a scribe section that is disposed to divide the element section into a plurality of portions and that is configured to be used as a cutting allowance for dicing; forming an oxide layer on an upper surface of the semiconductor layer located at the scribe section by a thermal oxidation process; forming a plurality of trenches in the semiconductor layer located at the element section so that the plurality of trenches extends from the upper surface of the semiconductor layer to the upper surface of the semiconductor substrate; forming a first epitaxial layer on the upper surface of the semiconductor layer located at the element section while filling the plurality of trenches with the first epitaxial layer so that a plurality of columns having different conductivity types is alternately arranged in the semiconductor layer so as to configurate a part of the semiconductor element, in which the first epitaxial layer has a crystal structure similar to the crystal structure of the semiconductor layer; forming a second epitaxial layer on the upper surface of the semiconductor layer located at the scribe section concurrently with the forming the first epitaxial layer, wherein the second epitaxial layer has a crystal structure different from the crystal structure of the semiconductor layer; reducing thicknesses of the first epitaxial layer and the second epitaxial layer until the oxide layer is exposed to an outside of the semiconductor device so that the upper surface of the semiconductor layer is planarized; forming a third epitaxial layer on the planarized upper surface of the semiconductor layer so that the third epitaxial layer has a step due to a difference in crystal structures at the element section and the scribe section; and arranging an element-forming mask on the upper surface of the third epitaxial layer using the step as a reference position and forming another part of the semiconductor element in the third epitaxial layer.

In this manufacturing method, the element section and the scribe section can be discriminated based on the step provided by the difference in the crystal structures.

According to a second aspect of the invention, a method of manufacturing a semiconductor, includes: preparing a semiconductor wafer that includes a semiconductor substrate and a semiconductor layer, in which the semiconductor layer is stacked on an upper surface of the semiconductor substrate and has a crystal structure similar to a crystal structure of the semiconductor substrate, and the semiconductor wafer includes an element section configured to have a semiconductor element and a scribe section that is disposed to divide the element section into a plurality of portions and that is configured to be used as a cutting allowance for dicing; forming an oxide layer on an upper surface of the semiconductor layer located at the scribe section by a thermal oxidation process; forming a plurality of trenches in the semiconductor layer located at the element section so that the plurality of trenches extends from an upper surface of the semiconductor layer to the upper surface of the semiconductor substrate; forming a first epitaxial layer on the upper surface of the semiconductor layer located at the element section while filling the plurality of trenches with the first epitaxial layer so that a plurality of columns having different conductivity types is alternately arranged in the epitaxial layer so as to configurate a part of the semiconductor element, wherein the first epitaxial layer has a crystal structure similar to the crystal structure of the semiconductor layer; forming a second epitaxial layer on the upper surface of the semiconductor layer located at the scribe section concurrently with the forming the first epitaxial layer, in which the second epitaxial layer has a crystal structure different from the crystal structure of the semiconductor layer; reducing thicknesses of the first epitaxial layer and the second epitaxial layer until the oxide layer is exposed to an outside of the semiconductor device so that the upper surface of the semiconductor layer is planarized; removing at least a part of the oxide layer until the upper surface of the semiconductor layer located under the oxide layer is exposed to the outside of the semiconductor device after the planarization is performed; forming a third epitaxial layer on the planarized upper surface of the semiconductor layer; and arranging an element-forming mask on the upper surface of the third epitaxial layer using a step provided by removing the part of the oxide layer as a reference position and forming another part of the semiconductor element in the third epitaxial layer.

In this manufacturing method, the element section and the scribe section can be discriminated based on the step provided by the removing the part of the oxide layer.

According to a third aspect of the invention, a semiconductor wafer includes a semiconductor substrate, a semiconductor layer, and an oxide layer. The semiconductor layer is disposed on a surface of the semiconductor substrate, and has a crystal structure similar to a crystal structure of the semiconductor substrate. The semiconductor layer includes an element section and a scribe section. The scribe section is disposed to divide the element section into a plurality of portions and is configurated to be used as a cutting allowance for dicing. Each of the portions includes a column structure in which a plurality of columns having different conductivity types is arranged alternately. The oxide layer is disposed on a surface of the scribe section to be exposed to an outside of the semiconductor wafer.

Because the oxide layer and the semiconductor layer have different optical properties, the element section and the scribe section can be discriminated. Furthermore, when an epitaxial layer is formed on the semiconductor wafer, a portion of the epitaxial layer formed at the element section inherits the crystal structure of the semiconductor layer, and another portion of the epitaxial layer formed at the scribe section does not inherit the crystal structure of the semiconductor layer because the oxide layer disposed on the semiconductor layer. When the crystal structure of the epitaxial layer is different between the element section and the scribe section, growing rate of the epitaxial layer is different between the element section and the scribe section, and thereby a thickness of the epitaxial layer is different between the element section and the scribe section. Thus, even when the epitaxial layer is formed on the semiconductor wafer, the element section and the scribe section can be discriminated based on a step provided by the difference in the crystal structures.

### BRIEF DESCRIPTION OF THE DRAWINGS

Additional objects and advantages of the present invention will be more readily apparent from the following detailed description of preferred embodiment when taken together with the accompanying drawings. In the drawings:

FIG. 1 is a plan view showing a semiconductor wafer according to an embodiment of the present disclosure;

FIG. 2 is a cross-sectional view showing the semiconductor wafer taken along line II-II in FIG. 1;

FIG. 3 is a cross-sectional view showing the semiconductor wafer taken along line III-III in FIG. 1;

FIGS. 4A-4C are schematic cross-sectional views showing a part of a manufacturing method of a semiconductor device according to the embodiment;

FIGS. 5A-5D are schematic cross-sectional views showing another part of the manufacturing method following the part shown in FIGS. 4A-4C;

FIG. 6 is a plan view of a semiconductor wafer according to a modification of the embodiment;

FIGS. 7A and 7B are schematic cross-sectional views showing a part of manufacturing method according to the modification;

FIGS. 8A-8D are schematic cross-sectional views showing a part of manufacturing method according to a related art; and

FIGS. 9A and 9B are cross-sectional views showing a semiconductor wafer according to the related art.

### DETAILED DESCRIPTION OF THE PREFERRED EMBODIMENT

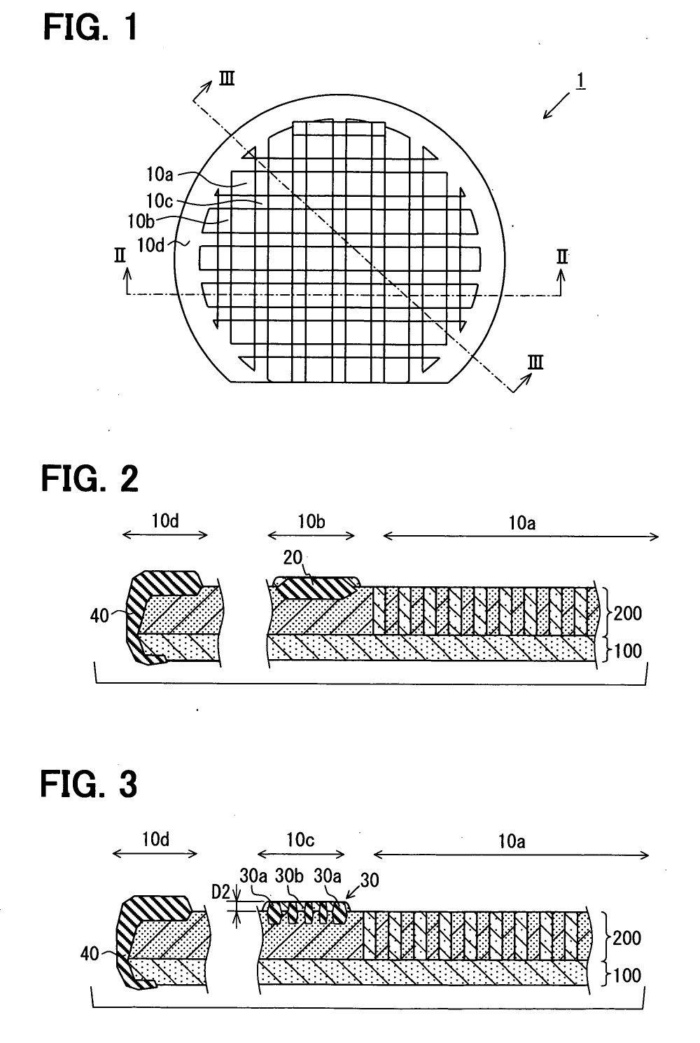

A semiconductor wafer 1 according to an embodiment of the present disclosure will be described with reference to FIGS. 1-3. As shown in FIGS. 2 and 3, the semiconductor wafer 1 includes a high concentration N-type semiconductor substrate 100, e.g., made of single crystal silicon, and a low concentration N-type semiconductor layer 200 also made of single crystal silicon. Thus, silicon in the semiconductor wafer 1 and silicon in the semiconductor layer 2 have single crystal structures similar to each other. The semiconductor layer 200 is stacked on an upper surface of the semiconductor substrate 100.

The semiconductor wafer 1 has a column structure in the semiconductor layer 200. In the column structure, columns having different conductivity types are arranged alternately. For example, at a later process, an epitaxial layer (not shown) is deposited on an upper surface of the semiconductor layer 200 by an epitaxy method, and a metal-oxide semiconductor (MOS) transistor element having a three-dimensional structure or a transistor element having a super junction structure is formed in the epitaxial layer. In the present case, the column structure configurated in the semiconductor layer 200 functions as a part of the transistor element.

As shown in FIG. 1, a center portion of the semiconductor wafer 1 includes an element section 10a and a scribe section 10b. A semiconductor element including the transistor element is formed at the element section 10a, and the scribe section 10b is used as a cutting allowance for dicing. Specifically, the scribe section 10b has a plurality of linear portions that divides the element section 10a into a plurality of rectangular portions. The liner portions of the scribe section 10b cross each other at a crossing section 10c. As shown in FIG. 2, on the whole upper surface of the semiconductor layer 200 located at the scribe section 10b, a first oxide layer 20, e.g., made of silicon dioxide (SiO₂), is formed so as to have a predetermined thickness. As shown in FIG. 3, the first oxide layer 20 located at the crossing section 10c is formed to have a predetermined alignment pattern. A portion of the first oxide layer 20 having the alignment pattern functions as an alignment mark 30, which shows a reference position of an element-forming mask for forming the semiconductor element.

At an outer peripheral section 10d of the semiconductor wafer 1, a second oxide layer 40, e.g., made of silicon dioxide, is formed to cover the upper surface of the semiconductor layer 200, side surfaces of semiconductor layer 200 and the semiconductor substrate 100, and a lower surface of the semiconductor substrate 100. The second oxide layer 40 has a predetermined thickness.

On the upper surface of the semiconductor wafer 1, the epitaxial layer (not shown) is deposited by the epitaxy method, and the semiconductor element is formed in the epitaxial layer and the semiconductor layer 200.

Before forming the epitaxial layer, the first oxide layer 20 and the alignment mark 30 are located on the upper surface of the semiconductor wafer 1 and are exposed to an outside of the semiconductor wafer 1. Thus, the element section 10a and the scribe section 10b can be discriminated based on a difference in optical properties (e.g., reflectivity) of the first oxide layer 20, the alignment mark 30, and the semiconductor layer 200.

When the epitaxial layer is formed, the epitaxial layer has a crystal structure similar to that of a layer on which the epitaxial layer is formed. Because the semiconductor layer 200 located at the element section 10a has the single crystal structure, the epitaxial layer formed at the element section 10a has the single crystal structure. However, the first oxide layer 20 and the alignment mark 30 are formed on the upper surface of the semiconductor layer 200 located at the scribe section 10b and the crossing section 10c, and the second oxide layer 40 is formed on the upper surface of the semiconductor layer 200 located at the outer peripheral section 10d. Thus, the epitaxial layer formed at the scribe section 10b, the crossing section 10c, and the outer peripheral section 10d do not have a single crystal structure similar to that of the semiconductor layer 200 but have polycrystalline structures.

When the epitaxial layer has the sections having different crystalline structures, a growing rate of the epitaxial layer differs from section to section, and thereby a thickness of the epitaxial layer differs from section to section. Specifically, a growing rate of the epitaxial layer having the single crystal structure is smaller than that of the epitaxial layer having the polycrystalline structure. Thus, a thickness of the epitaxial layer formed at the element section 10a is smaller than that of the epitaxial layer formed at the scribe section 10b, the crossing section 10c, or the outer peripheral section 10d. Because the thickness of the epitaxial layer differs from section to section, the epitaxial layer has steps. As a result, even when the epitaxial layer is formed and the first oxide layer 20 and the alignment mark 30 are buried in the epitaxial layer, the element section 10a and the scribe section 10b can be discriminated based on the steps due to a difference in the crystal structures.

As described above, the first oxide layer 20 located at the crossing section 10c is formed to have the alignment pattern functioning as the alignment mark 30. For example, the alignment mark 30 includes a first portion 30a at which the first oxide layer 20 is formed and a second portion 30b at which the first oxide layer 20 is not formed. The first portion 30a is made of silicon dioxide similar to the first oxide layer 20, and the second portion 30b is made of single crystal silicon. Thus, even after the epitaxial layer is formed and the alignment mark 30 is buried in the epitaxial layer, a protruding part corresponding to the first portion 30a is formed on an upper surface of the epitaxial layer. Thereby, the predetermined alignment pattern of the alignment mark 30 is transferred to the upper surface of the epitaxial layer. As a result, the element section 10a and the scribe section 10b can be discriminated based on the protruding part (i.e., transferred alignment pattern) and the element-forming mask can be positioned with high accuracy.

When the epitaxial layer is formed on the upper surface of the semiconductor layer 200, the epitaxial layer may be also formed on a surface of the second oxide layer 40. In the present case, impurities of the semiconductor substrate 100 may diffuse to the epitaxial layer formed on the semiconductor layer 200 through the lower surface of the semiconductor substrate 100 and the epitaxial layer formed on the second oxide layer 40.

However, in the semiconductor wafer 1, an upper surface and a lower surface of the second oxide layer 40 are exposed to the outside of the semiconductor wafer 1. Thus, the above-described diffusing route is disconnected, and the impurities of the semiconductor substrate 100 are reduced from diffusing.

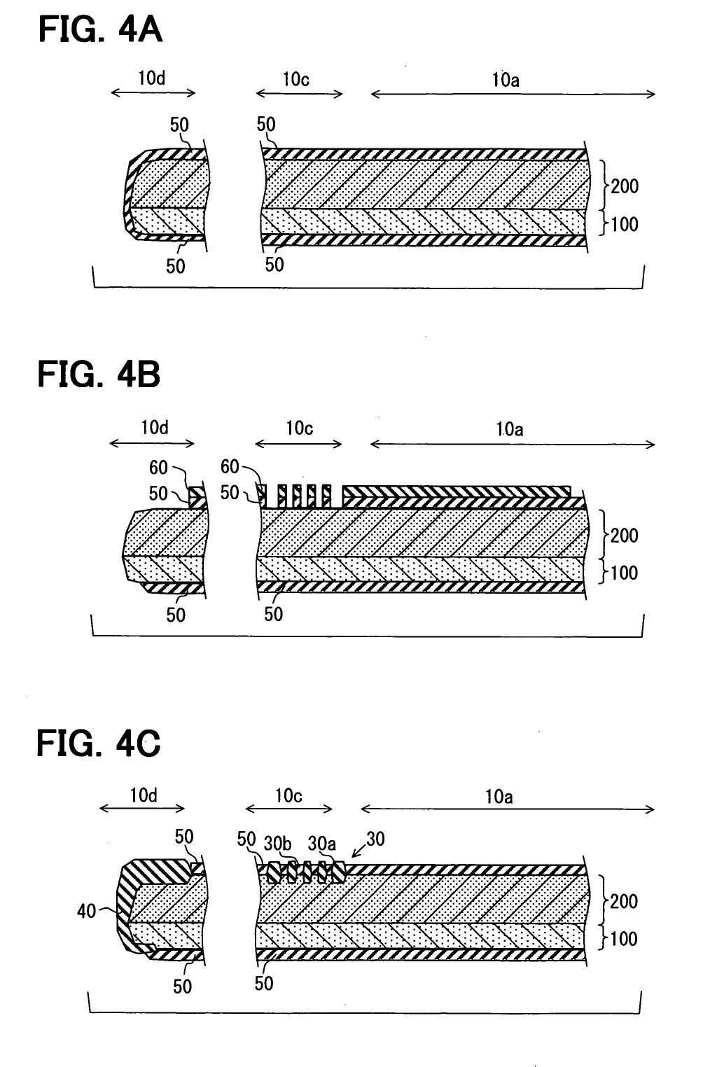

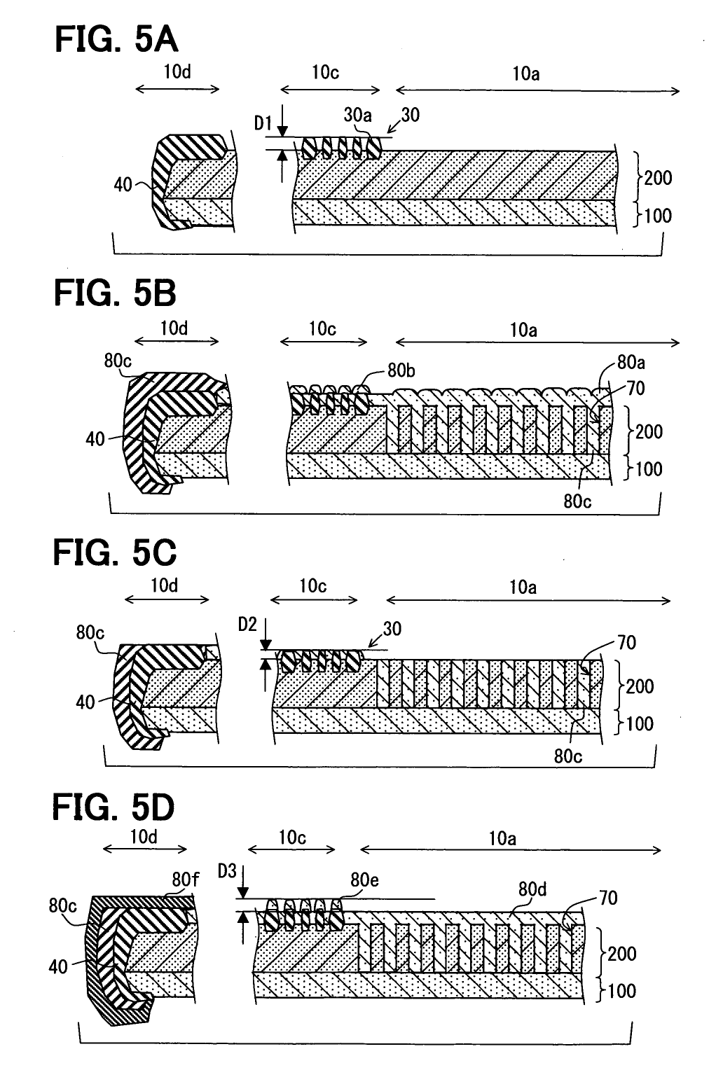

A method of manufacturing a semiconductor device including the semiconductor wafer 1 will now be described with reference to FIGS. 4A to 5D.

At first, the high concentration N-type semiconductor substrate 100, e.g., made of single crystal silicon, is prepared. Then, the low concentration N-type semiconductor layer 200 having the crystal structure similar to that of the semiconductor substrate 100 is formed on the upper surface of the semiconductor substrate 100 by the epitaxy method. After the semiconductor wafer including the semiconductor substrate 100 and the semiconductor layer 200 is formed, an oxide layer forming process shown in FIGS. 4A-4C are performed.

At first, as shown in FIG. 4A, a silicon nitride layer (SiN) is formed on an upper surface of the semiconductor layer 200, side surfaces of the semiconductor layer 200 and the semiconductor substrate 100, and a lower surface of the semiconductor substrate 100 by a low pressure chemical-vapor-deposition (low pressure CVD) using silane (SiH₄) gas and ammonia (NH₃) gas. The silicon nitride layer has a thickness about 150 nm, for example, and functions as an oxide-layer forming mask 50. Then, a P-type photoresist 60 is applied to an upper surface of the silicon nitride layer by a spin coating to have a thickness about 1.25 μm, for example.

Next, portions of the semiconductor layer 200 and the semiconductor substrate 100, at which the first oxide layer 20, the alignment mark 30, and the second oxide layer 40 will be formed, are exposed to an outside of the semiconductor wafer by a photolithography and a dry etching. Specifically, the semiconductor wafer applied with the photoresist 60 on the upper surface of the silicon nitride layer is disposed in an exposure apparatus (not shown), and a laser light is irradiated to the photoresist 60 through a mask (not shown) having a predetermined pattern. Because the photoresist 60 is P-type, the irradiated portion of the photoresist 60 is removed and the other portion of the photoresist 60 remains on the silicon nitride layer. After the photoresist 60 is hardened by heating, e.g., at about 150° C., the silicon nitride layer is removed in plasma gas by the dry etching using the photoresist 60 as a mask. As a result, the oxide-layer forming mask 50 is formed as shown in FIG. 4B. At the outer peripheral section 10d, which has a dimension about 10 mm from an outer peripheral end to an inner peripheral side of the semiconductor wafer, the upper surface of the semiconductor layer 200, the side surfaces of the semiconductor layer 200 and the semiconductor substrate 100, and the lower surface of the semiconductor substrate 100 (i.e., the portion where the second oxide layer 40 will be formed) are exposed to the outside of the semiconductor wafer through the oxide-layer forming mask 50. At the crossing section 10c, the portions where the first oxide layer 20 and the alignment mark 30 will be formed are exposed to the outside of the semiconductor wafer through the oxide-layer forming mask 50. The remaining photoresist 60 is removed by an ashing using oxygen plasma, for example.

Then, the semiconductor wafer having the oxide-layer forming mask 50 is disposed in an oxidizing atmosphere, e.g., at about 950° C., and an wet oxidation using steam is performed, e.g., for about 620 minutes. Thereby, the exposed portions that are not covered by the oxide-layer forming mask 50 are selectively oxidized. Thus, as shown in FIG. 4C, the oxide layer as the alignment mark 30 is formed at the crossing section 10c, and the second oxide layer 40 is formed at the outer peripheral section 10d. Furthermore, the first oxide layer 20 is formed at the scribe section 10b as shown in FIG. 2.

After the oxide-layer forming process, the oxide-layer forming mask 50 is removed, and a trench forming process for forming the column structure in the semiconductor layer 200 is performed.

In the trench forming process, as shown in FIG. 5A, an etching mask (not shown) is arranged on the upper surfaces of the alignment mark 30 and the semiconductor layer 200 based on a first step D1 generated by removing the oxide-layer forming mask 50. Then, the semiconductor layer 200 located at the element section 10a is etched through the etching mask, and thereby a plurality of trenches 70 extending from the upper surface of the semiconductor layer 200 to the upper surface of the first substrate 100 is formed. After removing the etching mask, an epitaxial-layer forming process is performed.

In the epitaxial-layer forming process shown in FIG. 5B, the epitaxial layer is formed on the upper surface of the semiconductor substrate 100 that is exposed to the outside of the semiconductor wafer through the trenches 70 and the semiconductor layer 200. Specifically, a first epitaxial layer 80a is formed on the upper surface of the semiconductor substrate 100 that is exposed to the outside of the semiconductor wafer through the trenches 70, and thereby the trenches 70 are filled with the first epitaxial layer 80a. After filling the trenches 70, the first epitaxial layer 80a is further deposited on the upper surface of the semiconductor layer 200 located at the element section 10a and the upper surfaces of the trenches 70. The first epitaxial layer 80a located in the trenches 70 has the single crystal structure by inheriting the crystal structure from the semiconductor substrate 100. Additionally, the first epitaxial layer 80a located on the upper surface of the semiconductor layer 200 has the single crystal structure by inheriting the crystal structure from the semiconductor layer 200. An upper surface of the first epitaxial layer 80a is uneven due to the trenches 70 formed in the semiconductor layer 200 located at element section 10a. At the scribe section 10b and the crossing section 10c, a second epitaxial layer 80b is deposited on the upper surface of the first oxide layer 20 and the first portion 30a of the alignment mark 30. Because the second epitaxial layer 80b does not inherit the crystal structure from the semiconductor layer 200, the second epitaxial layer 80b has the polycrystalline structure. An upper surface of the second epitaxial layer 80b is also uneven due to the alignment mark 30 formed in the semiconductor layer 200 located at the crossing section 10c. At the outer peripheral section 10d, a third epitaxial layer 80c is deposited on a surface of the second oxide layer 40. Because the third epitaxial layer 80c does not inherit the crystal structure from the semiconductor layer 200, the third epitaxial layer 80c has the polycrystalline structure.

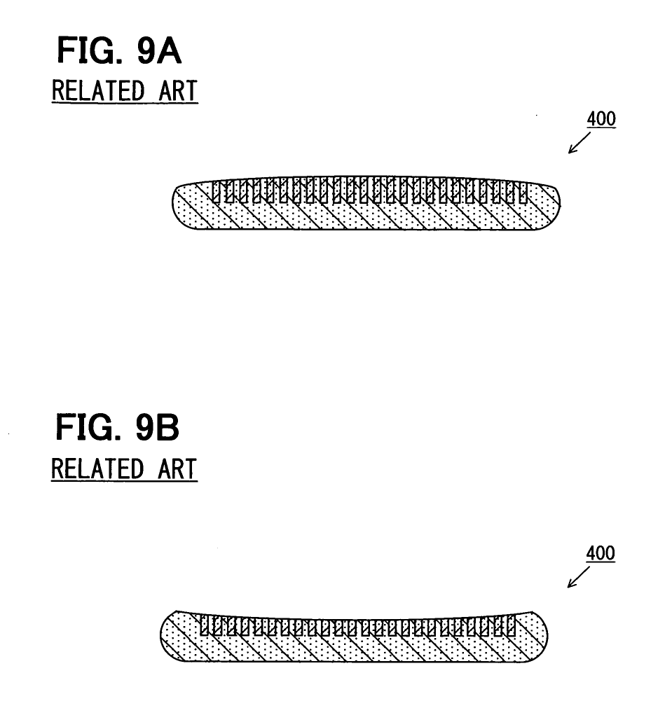

After the epitaxial-layer forming process, a planarization process is performed to planarize the upper surface of the semiconductor layer 200 having the unevenness. In the planarization process, thicknesses of the first epitaxial layer 80a, the second epitaxial layer 80b, and the third epitaxial layer 80c are reduced, e.g., by a mechanical polishing using a polishing cloth. Specifically, the second epitaxial layer 80b is polished until the first oxide layer 20 and the alignment mark 30 are exposed to the outside of the semiconductor wafer, and the third epitaxial layer 80c is polished until the second oxide layer 40 is exposed to the outside of the semiconductor wafer. Hardness of each of the first oxide layer 20, the alignment mark 30, and the second oxide layer 40 is larger than that of the epitaxial layers 80a-80c. Furthermore, resistances of the first oxide layer 20, the alignment mark 30, and the second oxide layer 40 to the polishing cloth are larger than those of the epitaxial layers 80a-80c. Thus, a polishing rate is reduced after the first oxide layer 20, the alignment mark 30, and the second oxide layer 40 are exposed to the outside of the semiconductor wafer, and it takes a long time to planarize the semiconductor layer 200. Therefore, by monitoring the polishing rate of the semiconductor layer 200, and finishing the mechanical polishing when the polishing rate is reduced rapidly, the semiconductor wafer, in which the upper surface of the semiconductor layer 200 is planarized as shown in FIG. 5C, can be obtained. In the manufacturing method shown in FIGS. 4A-5D, the planarization can be finished with a high degree of certainty, based on the difference between the hardness of each of the first oxide layer 20, the alignment mark 30 and the second oxide layer 40, and the hardness of the epitaxial layers 80a-80c. Thus, the center portion of the semiconductor wafer is reduced from being thinner or thicker than an outer peripheral portion as shown in FIGS. 9A and 9B. As shown in FIG. 5C, each of the upper surface of the semiconductor layer 200 located at the element section 10a, the upper surface of the alignment mark 30 located at the crossing section 10c, and the upper surface of the second oxide layer 40 located at the outer peripheral section 10d are planarized. However, a second step D2 is provided between the upper surface of the semiconductor layer 200 located at the element section 10a and the upper surface of the alignment mark 30 located at the crossing section 10c. In the mechanical polishing, the semiconductor wafer is polished by being pressed against the polishing cloth that is soft. Because the polishing cloth deforms in accordance with a shape of the semiconductor wafer, the upper surface of the first epitaxial layer 80a and the upper surface of the second epitaxial layer 80b are polished in a manner similar to each other, and thereby the second step D2 can be provided. By removing the third epitaxial layer 80c deposited on the second oxide layer 40, the above-described semiconductor wafer 1 shown in FIGS. 1-3 is formed.

Next, an epitaxial-layer reforming process is performed for forming a fourth epitaxial layer 80d on the planarized upper surface of the semiconductor layer 200 of the semiconductor wafer, so that the other part of the semiconductor element can be formed in the fourth epitaxial layer.

Before the epitaxial-layer reforming process, the first oxide layer 20 and the alignment mark 30 are exposed to the outside of the semiconductor wafer, as shown in FIG. 5C. Thus, the element section 10a and the scribe section 10b can be discriminated based on the difference in the optical properties, e.g., the reflectivities.

When the epitaxial-layer reforming process is started, the fourth epitaxial layer 80d deposited on the semiconductor layer 200 has the single crystal structure by inheriting the crystal structure of the semiconductor layer 200. On the upper surface of the semiconductor wafer located at the scribe section 10b and the crossing section 10c, a fifth epitaxial layer 80e is deposited. Because the first oxide layer 20 and the alignment mark 30 are formed on the upper surface of the semiconductor layer 200 located at the scribe section 10b and the crossing section 10c, a part of the fifth epitaxial layer 80e deposited on the first oxide layer 20 and the alignment mark 30 has a polycrystalline structure without inheriting the crystal structure of the semiconductor layer 200. The other part of the fifth epitaxial layer 80e deposited directly on the upper surface of the semiconductor layer 200 has the single crystal structure by inheriting the crystal structure of the semiconductor layer 200. On the upper surface of the outer peripheral section 10d, the second oxide layer 40 is formed. Thus, a sixth epitaxial layer 80f deposited at the outer peripheral section 10d has a polycrystalline structure without inheriting the crystal structure of the semiconductor layer 200.

Because the growing rate of the epitaxial layer having the single crystal structure is later than the epitaxial layer having the polycrystalline structure, the fourth epitaxial layer 80d formed at the element section 10a has a thickness smaller than those of the fifth epitaxial layer 80e formed at scribe section 10b and the crossing section 10c, and the sixth epitaxial layer 80f formed at the outer peripheral section 10d. Thus, a third step D3 is provided between an upper surface of the fourth epitaxial layer 80d and an upper surface of the fifth epitaxial layer 80e. As a result, even when the epitaxial-layer reforming process is performed and the first oxide layer 20 and the alignment mark 30 are buried in the fifth epitaxial layer 80e, the element section 10a and the scribe section 10b can be discriminated based on the third step D3 provided due to the difference in the crystal structures. Especially, on the upper surface of the fifth epitaxial layer 80e formed on the alignment mark 30, the alignment pattern of the alignment mark 30 is transferred. Thus, the element section 10a and the scribe section 10b can be discriminated with high accuracy, and thereby the element-forming mask can be positioned with high accuracy.

In an element forming process, the other part of the semiconductor element is formed mainly on the fourth epitaxial layer 80d. A detail of the element forming process varies according to a type of the semiconductor element, and is well known in the art. Thus, the detail of the element forming process will not described in the present disclosure. The semiconductor device including the MOS transistor element having the three-dimensional structure or the transistor element having the super junction structure is formed by using the first step D1, especially, the transferred alignment pattern, as the reference position of the element-forming mask.

### Other Embodiments

Although the present invention has been fully described in connection with the preferred embodiments thereof with reference to the accompanying drawings, it is to be noted that various changes and modifications will become apparent to those skilled in the art.

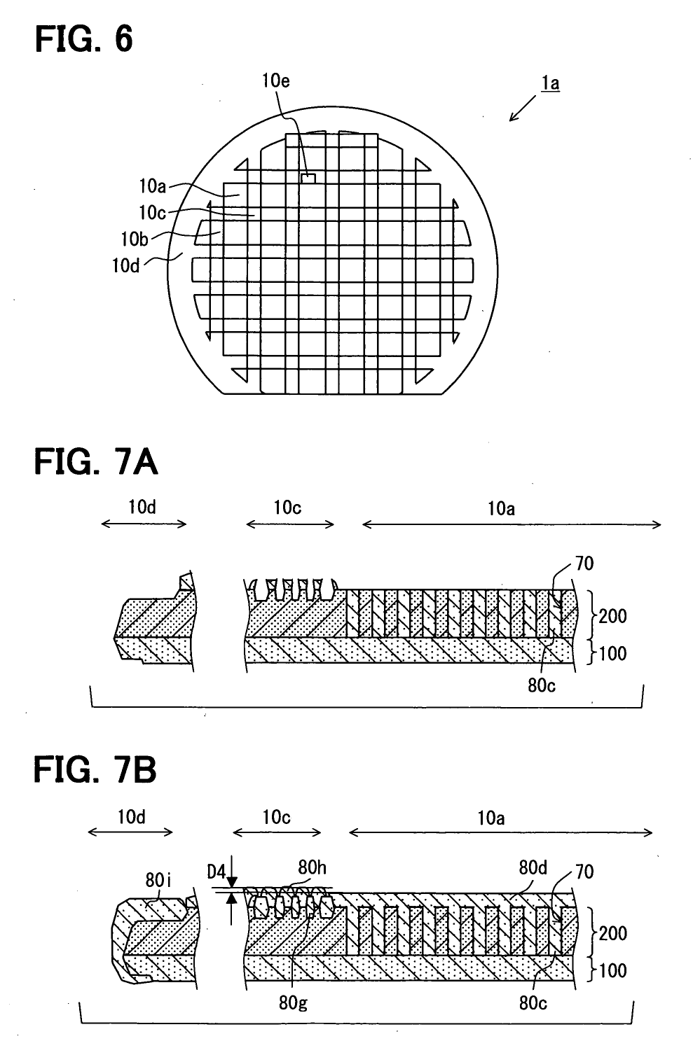

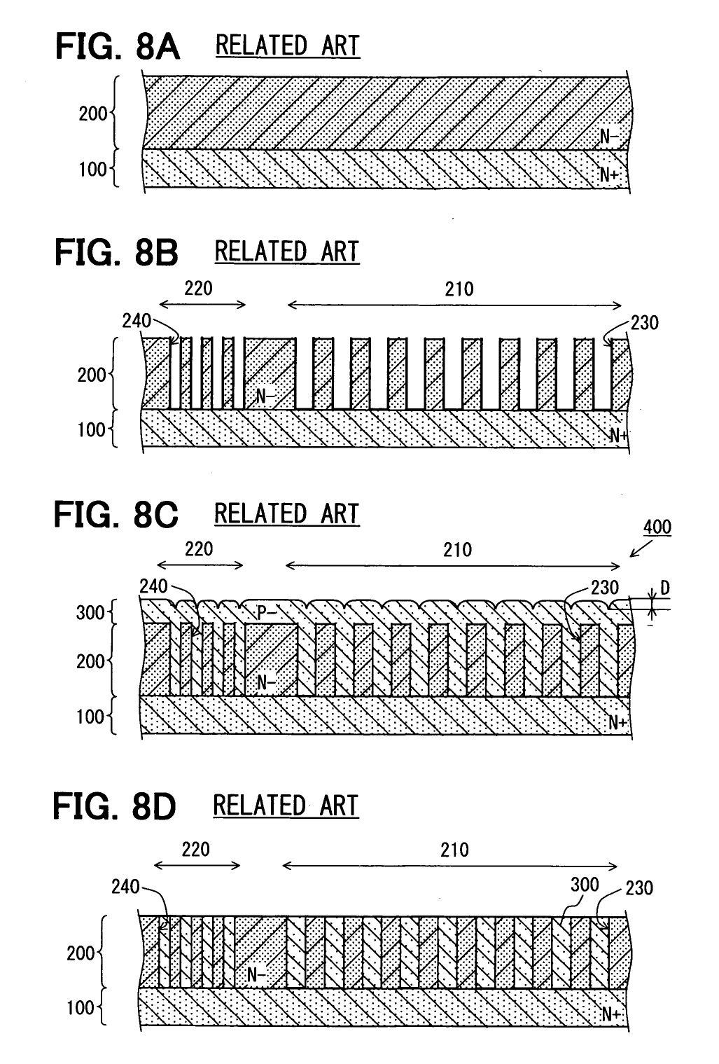

In the semiconductor wafer 1, the alignment mark 30 is formed at the first oxide layer 20 located at the crossing section 10c, as an example. Alternatively, as shown in FIG. 6, a semiconductor wafer 1a, in which the alignment mark 30 is formed at the first oxide layer 20 located at a section 10e adjacent to the crossing section 10c, may be used instead of the semiconductor wafer 1. As long as the alignment mark 30 is formed at the first oxide layer 20, effects similar to those of the semiconductor wafer 1 can be obtained.

In the semiconductor wafers 1 and 1a, the scribe section 10b has the plural linear portions for dividing the element section 10a into the plural rectangular portions, as an example. Alternatively, the element section 10a may be divided into plural portions each having a predetermined shape, for example, a polygonal shape or a circular shape. The scribe section 10b is disposed to divide the element section 10a into the plural portions each having the predetermined shape, and is used as the cutting allowance for dicing.

In the semiconductor wafers 1 and 1a, the second oxide layer 40 having the predetermined thickness is formed to cover the upper surface, the side surface and the lower surface of the outer peripheral section 10d, and both the upper surface and the lower surface of the second oxide layer 40 are exposed to the outside of the semiconductor wafers 1 and 1a. Alternatively, at least one of the upper surface and the lower surface of the second oxide layer 40 may be exposed to the outside of the semiconductor wafer 1 and 1a. In this case, the impurities of the semiconductor substrate 100 are prevented from diffusing through the epitaxial layer formed on the upper surface of the second oxide layer 40. Thus, effects similar to those of the semiconductor wafer 1 can be obtained. When the impurities does not diffuse to an outside of the semiconductor substrate 100 or when the impurities diffused from the semiconductor substrate 100 does not affect an operation of the semiconductor element formed in the semiconductor layer 200, the second oxide layer 40 is not required.

In the semiconductor wafers 1 and 1a, the oxide-layer forming mask 50 is pattern-formed to have the predetermined alignment pattern and the thermal oxidation is performed so that the alignment mark 30 having the predetermined pattern is formed, as an example. Alternatively, the alignment mark 30 having the predetermined alignment pattern may be formed by etching the first oxide layer 20 that is formed by a thermal oxidation. Also in this case, effects similar to those of the semiconductor wafer 1 can be obtained.

In the trench forming process in the above-described manufacturing method shown in FIG. 5A, the etching mask is arranged based on the first step D1 that is generated by removing the oxide-layer forming mask 50 and that is provided between the upper surface of the semiconductor layer 200 and the upper surfaces of the first oxide layer 20 and the alignment mark 30. Alternatively, the etching mask may be arranged based on a difference between the optical properties of the first oxide layer 20 and the alignment mark 30, and the optical property of the semiconductor layer 200, for example, because the first oxide layer 20 and the alignment mark 30 are exposed to the outside of the semiconductor wafer.

In the planarization process shown in FIG. 5C, the planarization is finished based on the difference between the hardness of the epitaxial layers 80a-80c and the hardness of each of the first oxide layer 20, the alignment mark 30, and the second oxide layer 40, as an example. Alternatively, the planarization may be finished based on a difference between the hardness of each of the first epitaxial layer 80a and second epitaxial layer 80b and the hardness of each of the first oxide layer 20 and the alignment mark 30, for example. Alternatively, the planarization may be finished based on a difference between the hardness of the third epitaxial layer 80c and the hardness of the second oxide layer 40. Also in these cases, effects similar to the manufacturing method shown in FIG. 5C can be obtained.

In the oxide-layer forming process shown in FIG. 4A, the thermal oxidation is performed after the oxide-layer forming mask 50 is formed on the semiconductor wafer by the low pressure CVD. In this case, the oxide-layer forming mask 50 having a small thickness is formed on the upper and lower surface of the semiconductor wafer. Because, the oxide-layer forming mask can be formed with high accuracy, the first oxide layer 20, which is formed by the thermal oxidation using the oxide-layer forming mask 50, can be formed with high accuracy. Alternatively, the thermal oxidation is performed using the oxide-layer forming mask 50 formed by a plasma CVD. In this case, the oxide-layer forming mask 50 can be formed only one of the upper surface and the lower surface of the semiconductor wafer. On a surface without the oxide-layer forming mask 50, an oxide layer is formed by the thermal oxidation. The oxide layer is harder than the epitaxial layer. Thus, a warp of the semiconductor wafer can be reduced. The oxide-layer forming mask 50 may be formed by various methods as long as the first oxide layer 20, the alignment mark 30, and the second oxide layer 40 are formed with high accuracy by the thermal oxidation.

In the element forming process shown in FIG. 5D, the semiconductor element is formed in the semiconductor layer 200 by using the third step D3 generated in the fourth to sixth epitaxial layer 80d-80f due to the difference in the crystal structures, as the reference point, as an example. However, the reference point is not limited to the third step D3. For example, as shown in FIG. 7A, the first oxide layer 20, the alignment mark 30, and the second oxide layer 40 may be removed until the upper surface of the semiconductor layer 200 is exposed to the outside of the semiconductor wafer, after the planarization process shown in FIG. 5C is performed. Then, in an element forming process shown in FIG. 7B, the fourth epitaxial layer 80d is formed on the semiconductor layer 200 located at the element section 10a. On the upper surface of the semiconductor layer 200 located at the crossing section 10c and the scribe section 10b, a seventh epitaxial layer 80g is formed at a portion from which the alignment mark 30 (the first oxide layer 20) has been removed, and an eighth epitaxial layer 80h is formed at the other portion at which the alignment mark 30 (the first oxide layer 20) has not been formed. Additionally, a ninth epitaxial layer 80i is formed at the upper surface of the semiconductor layer 200, the side surfaces of the semiconductor layer 200 and the semiconductor substrate 100, and the lower surface of the semiconductor substrate 100 that are located at the outer peripheral section 10d. Between the upper surface of the fourth epitaxial layer 80d and the upper surface of the eighth epitaxial layer 80h, a fourth step D4 is generated by removing the alignment mark 30 (the first oxide layer 20). Thus, the semiconductor element may be formed in the semiconductor layer 200 located at the element section 10a by using the fourth step D4 as the reference position. In the present case, the seventh epitaxial layer 80g and the eighth epitaxial layer 80h have single crystal structures similar to each other, and thereby growing rates of the epitaxial layer 80g and the eighth epitaxial layer 80h are similar to each other. However, because the planarization is performed before forming the fourth epitaxial layer 80d, the seventh epitaxial layer 80g, and the eighth epitaxial layer 80h, the fourth step D4 generated by removing the alignment mark 30 (the first oxide layer 20) remains on the upper surfaces of the fourth epitaxial layer 80d and the eight epitaxial layer 80h even after the fourth epitaxial layer 80d, the seventh epitaxial layer 80g, and the eighth epitaxial layer 80h grow. Thus, the fourth step D4 can be used as the reference position of the element-forming mask, and the element section 10a and the scribe section 10b can be discriminated. The second oxide layer 40 is not required to be removed for providing the fourth step D4.

In the above-describe manufacturing method of the semiconductor device, the oxide-layer forming mask 50 formed at the upper surface of the semiconductor layer 200, the side surfaces the semiconductor layer 200 and the semiconductor substrate 100, and the lower surface of the semiconductor substrate 100, as shown in FIG. 4A. Then, a part of the oxide-layer forming mask 50 located on the upper surface and the lower surface of the semiconductor wafer located at the outer peripheral section 10d and the side surface of the semiconductor wafer are removed by photolithography and etching. Additionally, in the oxide layer forming process shown in FIG. 4A, the second oxide layer 40 is formed on an the upper surface of the semiconductor layer 200 located at the outer peripheral section 10d, the side surface of the semiconductor layer 200 and the semiconductor substrate 100, and the lower surface of the semiconductor substrate 100 located at the outer peripheral section 10d. Alternatively, the oxide-layer forming process may be performed without removing the oxide-layer forming mask 50 from the upper surface of the semiconductor layer 200 located at the outer peripheral section 10d, the side surface of the semiconductor layer 200 and the semiconductor substrate 100, and the lower surface of the semiconductor substrate 100 located at the outer peripheral section 10d. In this case, the second oxide layer 40 is not formed. However, effects similar to the above-described manufacturing method can be obtained.

Such changes and modifications are to be understood as being within the scope of the present invention as defined by the appended claims.

What is claimed is:

1. A method of manufacturing a semiconductor device, comprising:
preparing a semiconductor wafer that includes a semiconductor substrate and a semiconductor layer, wherein the semiconductor layer is stacked on an upper surface of the semiconductor substrate and has a crystal structure similar to a crystal structure of the semiconductor substrate, and the semiconductor wafer further includes an element section configured to have a semiconductor element and a scribe section that is disposed to divide the element section into a plurality of portions and that is configured to be used as a cutting allowance for dicing;
forming an oxide layer on an upper surface of the semiconductor layer located at the scribe section by a thermal oxidation process;
forming a plurality of trenches in the semiconductor layer located at the element section so that the plurality of trenches extends from the upper surface of the semiconductor layer to the upper surface of the semiconductor substrate;
forming a first epitaxial layer on the upper surface of the semiconductor layer located at the element section while filling the plurality of trenches with the first epitaxial layer so that a plurality of columns having different conductivity types is alternately arranged in the semiconductor layer so as to configurate a part of the semiconductor element, wherein the first epitaxial layer has a crystal structure similar to the crystal structure of the semiconductor layer;
forming a second epitaxial layer on the upper surface of the semiconductor layer located at the scribe section concurrently with the forming the first epitaxial layer, wherein the second epitaxial layer has a crystal structure different from the crystal structure of the semiconductor layer;
reducing thicknesses of the first epitaxial layer and the second epitaxial layer until the oxide layer is exposed to an outside of the semiconductor device so that the upper surface of the semiconductor layer is planarized;
forming a third epitaxial layer on the planarized upper surface of the semiconductor layer so that the third epitaxial layer has a first step due to a difference in crystal structures at the element section and the scribe section; and
arranging an element-forming mask on the upper surface of the third epitaxial layer using the first step as a reference position and forming another part of the semiconductor element in the third epitaxial layer.

2. The method according to claim 1, wherein:
the scribe section has a plurality of linear portions that crosses each other at a crossing section; and
the forming the oxide layer includes forming the oxide layer located at the crossing section so as to have a predetermined alignment pattern.

3. The method according to claim 1, wherein:
the forming the oxide layer includes forming an outer-peripheral oxide layer to cover upper and lower surfaces of an outer peripheral section of the semiconductor wafer and a side surface of the semiconductor wafer;
the forming the first and the second epitaxial layers includes forming a fourth epitaxial layer on an upper surface of the outer-peripheral oxide layer so that the fourth epitaxial layer has a crystal structure different from the crystal structure of the semiconductor layer; and
the reducing the thicknesses includes reducing a thickness of the fourth epitaxial layer until the upper surface of the outer-peripheral oxide layer is exposed to the outside of the semiconductor device, and the planarization is finished based on a difference between a hardness of the fourth epitaxial layer and a hardness of the outer-peripheral oxide layer.

4. The method according to claim 3, further comprising removing the outer-peripheral oxide layer after the planarization is performed.

5. The method according to claim 1, wherein the forming the oxide layer includes forming an oxide-layer forming mask on the semiconductor wafer by a low pressure chemical-vapor-deposition before the thermal oxidation process is performed.

6. The method according to claim 1, wherein the forming the oxide layer includes forming an oxide-layer forming mask on the semiconductor wafer by a plasma chemical-vapor-deposition before the thermal oxidation process is performed.

7. The method according to claim 1, wherein:
the plurality of trenches is formed by an etching process; and
an etching mask is arranged based on a second step that is provided between the upper surface of the oxide layer and the upper surface of the semiconductor layer during the forming the oxide layer.

8. The method according to claim 1, wherein the planarization is finished based on a difference between a hardness of the second epitaxial layer and a hardness of the oxide layer.

9. The method according to claim 1, wherein:
each of the semiconductor substrate, the semiconductor layer, and the first epitaxial layer has a single crystal structure; and
the second epitaxial layer has a polycrystalline structure.

10. A method of manufacturing a semiconductor device, comprising:
preparing a semiconductor wafer that includes a semiconductor substrate and a semiconductor layer, wherein the semiconductor layer is stacked on an upper surface of the semiconductor substrate and has a crystal structure similar to a crystal structure of the semiconductor substrate, and the semiconductor wafer further includes an element section configured to have a semiconductor element and a scribe section that is disposed to divide the element section into a plurality of portions and that is configured to be used as a cutting allowance for dicing;
forming an oxide layer on an upper surface of the semiconductor layer located at the scribe section by a thermal oxidation process;
forming a plurality of trenches in the semiconductor layer located at the element section so that the plurality of trenches extends from an upper surface of the semiconductor layer to the upper surface of the semiconductor substrate;
forming a first epitaxial layer on the upper surface of the semiconductor layer located at the element section while filling the plurality of trenches with the first epitaxial layer so that a plurality of columns having different conductivity types is alternately arranged in the epitaxial layer so as to configurate a part of the semiconductor element, wherein the first epitaxial layer has a crystal structure similar to the crystal structure of the semiconductor layer;
forming a second epitaxial layer on the upper surface of the semiconductor layer located at the scribe section concurrently with the forming the first epitaxial layer, wherein the second epitaxial layer has a crystal structure different from the crystal structure of the semiconductor layer;
reducing thicknesses of the first epitaxial layer and the second epitaxial layer until the oxide layer is exposed to an outside of the semiconductor device so that the upper surface of the semiconductor layer is planarized;
removing at least a part of the oxide layer until the upper surface of the semiconductor layer located under the oxide layer is exposed to the outside of the semiconductor device after the planarization is performed;
forming a third epitaxial layer on the planarized upper surface of the semiconductor layer; and
arranging an element-forming mask on the upper surface of the third epitaxial layer using a step provided by removing the part of the oxide layer as a reference position and forming another part of the semiconductor element in the third epitaxial layer.

11. The method according to claim 10, wherein:
the scribe section has a plurality of linear portions that crosses each other at a crossing section;
the forming the oxide layer includes forming a portion of the oxide layer adjacent to the crossing section so as to have a predetermined alignment pattern; and
the removing the oxide layer includes removing the portion of the oxide layer that has the predetermined pattern.

12. The method according to claim 10, wherein:
each of the semiconductor substrate, the semiconductor layer, and the first epitaxial layer has a single crystal structure; and
the second epitaxial layer has a polycrystalline structure.

13. A semiconductor wafer comprising:
a semiconductor substrate;
a semiconductor layer disposed on an upper surface of the semiconductor substrate, having a crystal structure similar to a crystal structure of the semiconductor substrate, and including an element section and a scribe section, wherein the scribe section is disposed to divide the element section into a plurality of portions and is configurated to be used as a cutting allowance for dicing, and each of the portions includes a column structure in which a plurality columns having different conductivity types is arranged alternately; and
an oxide layer disposed on an upper surface of the scribe section to be exposed to an outside of the semiconductor wafer.

14. The semiconductor wafer according to claim 13, wherein the oxide layer includes an alignment mark having a predetermined alignment pattern.

15. The semiconductor wafer according to claim 13, wherein:
the oxide layer includes a plurality of opening portions disposed to have a predetermined pattern; and
the upper surface of the scribe section is exposed to the outside of the semiconductor device through the opening portion.

16. The semiconductor wafer according to claim 13, further comprising:
an outer-peripheral oxide layer disposed to cover an outer peripheral portion of an upper surface of the semiconductor layer, side surfaces of the semiconductor layer and the semiconductor substrate, and an outer peripheral portion of a lower surface of the semiconductor substrate; and
at least one of an upper surface and a lower surface of the outer-peripheral oxide layer is exposed to the outside of the semiconductor wafer.

17. The semiconductor wafer according to claim 14, wherein:
the scribe section includes a plurality of linear portions that crosses each other at a crossing section; and
the alignment mark is disposed at a portion of the oxide layer that is located on the crossing section.

18. The semiconductor wafer according to claim 14, wherein:
the scribe section includes a plurality of linear portions that crosses each other at a crossing section; and
the alignment mark is disposed at a portion of oxide layer adjacent to the crossing section.

19. The semiconductor wafer according to claim 13, wherein each of the semiconductor substrate and the semiconductor layer has a single crystal structure.
